(19) United States
(12) Patent Application Publication
(10) Pub. No.: US 2020/0144056 A1
(43) Pub. Date: May 7, 2020

(54) METHOD OF FORMING A COBALT LAYER ON A SUBSTRATE

(71) Applicant: APPLIED MATERIALS, INC., Santa Clara, CA (US)

(72) Inventors: WEI LEI, CAMPBELL, CA (US); TAE HONG HA, SAN JOSE, CA (US); BYUNGHOON YOON, Cupertino, CA (US); YU LEI, FOSTER CITY, CA (US)

(21) Appl. No.: 16/179,906

(22) Filed: Nov. 3, 2018

(51) Int. Cl. H01L 21/02

(52) U.S. Cl. CPC H01L 21/02491; H01L 21/02211; H01L 21/02373; H01L 21/02389

(57) ABSTRACT

Methods and apparatus for forming a cobalt layer on a substrate disposed in a process chamber are disclosed herein. In the present disclosure, exposing a substrate to a first process gas including a bonding agent in an amount sufficient to facilitate bonding or adhesion of cobalt to a first surface of the substrate; and depositing cobalt upon the first surface of the substrate to form a cobalt layer is disclosed. The use of one or more silanes or molybdenum carbonyl compositions facilitate bonding or adhesion of cobalt to a first surface of the substrate. In the present disclosure, suitable substrates include substrates that do not easily bond or adhere to cobalt, such as titanium nitrate or tantalum nitrate.

### FIELD

Embodiments of the disclosure generally relate to the processing of semiconductor substrates. More particularly, embodiments of the disclosure relate to deposition of cobalt layers on semiconductor substrates while providing excellent adhesion or bonding between the cobalt layer and the substrate.

### BACKGROUND

The semiconductor processing industry continues to strive for larger production yields while increasing the uniformity of layers deposited on substrates. These same factors in combination with new materials also provide higher integration of circuits per unit area of the substrate. As circuit integration increases, the need for greater uniformity and process control regarding layer thickness rises. As a result, various technologies have been developed to deposit layers on substrates in a cost-effective manner, while maintaining control over the characteristics of the layer.

The inventors have found that depositing cobalt including thin layers of cobalt by conventional deposition methods, however, has several disadvantages. For example, thin cobalt layers, e.g., cobalt films less than 50 nanometers thick are fragile. Fragile cobalt films must be supported by a substrate and the degree to which the cobalt film can share the strength of the substrate depends upon the adhesion or bonding between the cobalt layer and the substrate. Thus, poor adhesion between a cobalt layer and a substrate is detrimental to the durability of the cobalt layer and devices made therefrom. Further, poor adhesion or bonding between a cobalt layer and a substrate leads to defects during semiconductor device manufacturing resulting in device yield loss. The inventors have also observed that cobalt adhesion or bonding may be especially poor depending upon the substrate material to which the cobalt is adhered to. Poor cobalt adhesion to a particular substrate may be problematic to down-stream processing such as deposition, patterning, and the like. For example, poor cobalt adhesion or bonding to a particular substrate may frustrate the manufacturing process as defects within a device such as a voids formed in a cobalt fill layer impede the ability to uniformly deposit additional layers or films thereon as needed. Moreover, the inventors have found that the cobalt defects are unpredictable and difficult to monitor and control.

Accordingly, the inventors have provided improved methods of depositing cobalt and cobalt containing layers.

### SUMMARY

Methods and apparatus for deposition of cobalt layers on semiconductor substrates using deposition techniques are provided herein.

In some embodiments, a method of forming a cobalt layer on a substrate disposed in a process chamber, includes: (a) exposing the substrate to a first process gas including a bonding agent in an amount sufficient to facilitate bonding or adhesion of cobalt to a first surface of the substrate; and (b) depositing cobalt upon the first surface of the substrate to form a cobalt layer.

In some embodiments, a method of depositing a cobalt film, includes: contacting a substrate with a bonding agent to form a treated substrate, wherein the bonding agent is provided in an amount sufficient to facilitate bonding of cobalt to the substrate; and subsequently depositing cobalt upon the treated substrate to form a cobalt layer.

In some embodiments, a method of bonding or adhering a cobalt layer to a substrate disposed in a process chamber, includes: (a) exposing the substrate to a first process gas including a bonding agent in an amount sufficient to facilitate bonding or adhesion of cobalt to a first surface of the substrate, wherein the first surface of the substrate includes titanium nitride (TiN), tantalum nitride (TaN), titanium silicon nitride (TiSiN), aluminum-doped titanium carbide (TiAlC), or combinations thereof; and (b) subsequently depositing cobalt upon the first surface of the substrate to form a cobalt layer, wherein the bonding agent is silane or other silicon containing material for forming a chemical bond between the cobalt and the substrate, or wherein the bonding agent is at least one of a molybdenum, ruthenium, or iridium material sufficient to react with cobalt to form a cobalt alloy atop the first surface of the substrate to which subsequently-depositing cobalt will adhere.

In some embodiments, a method of depositing a cobalt film, includes: contacting a substrate with a silane or other silicon containing material suitable for forming a chemical bond between cobalt and the substrate to form a treated substrate, or one or more of molybdenum, ruthenium, or iridium materials sufficient to react with cobalt to form a cobalt alloy atop the substrate to form a treated substrate, wherein the substrate comprises titanium nitride (TiN), tantalum nitride (TaN), titanium silicon nitride (TiSiN), aluminum-doped titanium carbide (TiAlC), or combinations thereof; and depositing cobalt upon the treated substrate to form a cobalt layer.

In some embodiments, a method of bonding or adhering a cobalt layer to a substrate disposed in a process chamber, includes: (a) exposing the substrate to a first process gas comprising a bonding agent in an amount sufficient to facilitate bonding or adhesion of cobalt to a first surface of the substrate; and (b) subsequently depositing cobalt upon the first surface of the substrate to form a cobalt layer, wherein a chemical bond is formed between the cobalt and the substrate, or wherein the bonding agent reacts with cobalt to form a cobalt alloy atop the substrate to which subsequently-depositing cobalt will adhere. In some embodiments, the bonding agent is suitable for promoting adhesion between the cobalt and the first surface of the substrate by forming a cobalt alloy mono-layer atop the substrate, and wherein the substrate comprises a layer of titanium nitride (TiN), tantalum nitride (TaN), titanium silicon nitride (TiSiN), aluminum-doped titanium carbide (TiAlC), or combinations thereof. In some embodiments, the bonding agent includes a metal species suitable for forming an alloy with cobalt, wherein the metal species is one or more carbonyl compounds such as molybdenum carbonyl, ruthenium compounds, or iridium compounds. In embodiments the metal species suitable for forming an alloy with cobalt are contacted with a substrate under conditions suitable for reacting with cobalt to form an alloy with cobalt. The alloy is formed on the first surface of the substrate to a predetermined thickness such as, a monolayer, or in embodiments between 0.5 to 1 angstroms. In embodiments, a suitable alloy formed atop the substrate as a monolayer comprises between 60 to 80 weight percent cobalt and 40 to 20 weight percent molybdenum, wherein the weight percent is based on the total weight of the alloy composition.

In some embodiments, a computer readable medium, having instructions stored thereon is provided which, when executed, cause a process chamber to perform a method of bonding or adhering a cobalt layer to a substrate disposed in the process chamber by (a) exposing the substrate to a first process gas including a bonding agent in an amount sufficient to facilitate bonding or adhesion of cobalt to a first surface of the substrate, wherein the first surface of the substrate includes titanium nitride (TiN), tantalum nitride (TaN), titanium silicon nitride (TiSiN), aluminum-doped titanium carbide (TiAlC), or combinations thereof; and (b) subsequently depositing cobalt upon the first surface of the substrate to form a cobalt layer, wherein the bonding agent is silane or other silicon containing material for forming a chemical bond between the cobalt and the substrate, or wherein the bonding agent is at least one of a molybdenum, ruthenium, or iridium material sufficient to react with cobalt to form a cobalt alloy atop the first surface of the substrate to which subsequently-depositing cobalt will adhere.

Other and further embodiments of the present invention are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a flow diagram of a method of forming a cobalt layer on a substrate disposed in a process chamber in accordance with embodiments of the present disclosure.

FIGS. 2A-2C respectively depict stages of fabrication including depositing a cobalt layer in accordance with embodiments of the present disclosure.

FIG. 3 depicts schematic view of a substrate processing system in accordance with some embodiments of the present disclosure.

FIG. 4 depicts a flow chart of a method of depositing a cobalt film in accordance with some embodiments of the present disclosure.

FIG. 5 depicts a flow chart of a method of bonding or adhering a cobalt layer to a substrate disposed in a process chamber.

FIG. 6 depicts a flow chart of a method of depositing a cobalt film in accordance with some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of the present disclosure provide methods of reducing or eliminating defects in cobalt layers or cobalt film. Further, embodiments of the present disclosure are useful when depositing cobalt upon a substrate, wherein the substrate does not typically show good adhesion, bonding, or poorly sticks together with a thin cobalt film.

The inventors have observed that treating a substrate in need thereof by contacting the substrate with a bonding agent facilitates and/or promotes adhesion or bonding between the treated substrate and a cobalt layer deposited upon the treated substrate. Good adhesion between the treated substrate and the cobalt layer advantageously reduces or eliminates defects that form due to poor adhesion or poor bonding. Reducing or eliminating defects in the completed cobalt layer leads to device yield increase, reduced manufacturing costs, and an increase in uniformity across a plurality of features during the formation of a semiconductor device. Increased uniformity enhances application of additional process layers as manufacturing continues. The inventors have also found that methods in accordance with the present disclosure advantageously provide cobalt films having significantly improved surface uniformity and production level throughput. In embodiments, high quality control is maintained upon cobalt layer deposition. In embodiments, good adhesion between a cobalt layer and substrate upon which the cobalt layer is disposed increases the durability of cobalt thin film devices. For example, good adhesion in thin cobalt film technology is important as cobalt films such as cobalt films having a thickness of less than 1 micrometer, or less than 50 nanometers are fragile and must be supported by more substantial substrates and the degree to which the cobalt film can share the strength of the substrate depends upon the adhesion between the two.

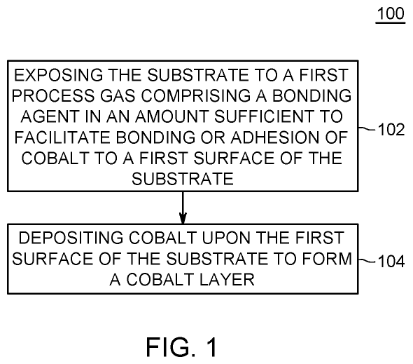

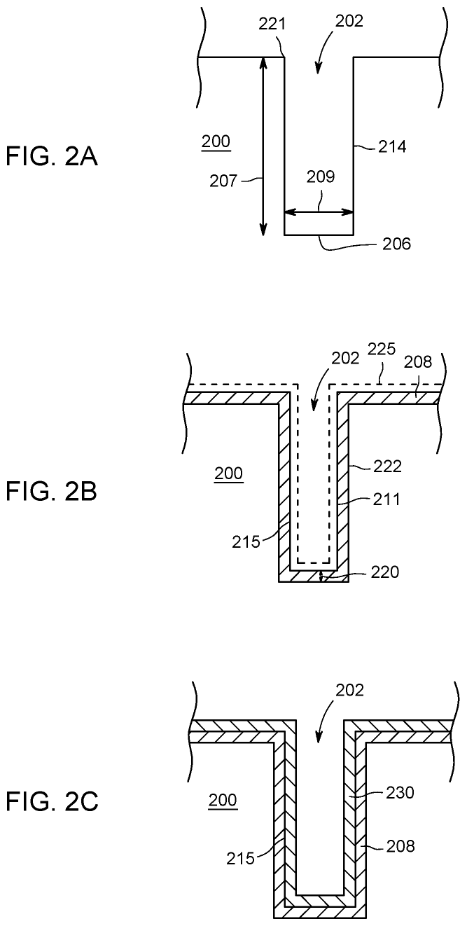

FIG. 1 is a flow diagram of a method 100 for forming a cobalt layer on a substrate disposed in a process chamber in accordance with some embodiments of the present disclosure. The method 100 is described below with respect to the stages of depositing a cobalt film as depicted in FIGS. 2A-2C and may be performed, for example, in a suitable cluster tool and process chambers. Exemplary processing systems that may be used to perform the methods disclosed herein may include, but are not limited to, any of the ENDURA®, CENTURA®, or PRODUCER® brand processing systems, commercially available from Applied Materials, Inc., of Santa Clara, Calif. Other process chambers, including ones available from other manufacturers, may also be suitably used in connection with the teachings provided herein.

The method 100 is typically performed on a substrate 200 provided to a processing volume of a process chamber. In some embodiments, as shown in FIG. 2A, the substrate 200 includes one or more features such as trench 202 (one shown in FIGS. 2A-C) to be filled with a cobalt layer 230, and extending towards a base 204 of the substrate 200. Although the following description is made with respect to one feature, the substrate 200 may include any number of features (such as a plurality of trenches 202, vias or the like) as described below.

The substrate 200 may be any suitable substrate for a semiconductor device. For example, the substrate 200 may include one or more of silicon (Si), silicon oxide (SiO₂), or the like. In embodiments, the substrate 200 may include, a low-k material (e.g., a material having a dielectric constant less than silicon oxide, or less than about 3.9), or the like. In addition, the substrate 200 may include additional layers of materials or may have one or more completed or partially completed structures or devices formed in or on the substrate 200 (not shown). In embodiments, the substrate 200 may be, for example, a doped or undoped silicon substrate, a III-V compound substrate, a silicon germanium (SiGe) substrate, an epi-substrate, a silicon-on-insulator (SOI) substrate, a display substrate such as a liquid crystal display (LCD), a plasma display, an electro luminescence (EL) lamp display, a light emitting diode (LED) substrate, a solar cell array, solar panel, or the like. In some embodiments, the substrate 200 may be a semiconductor wafer. In some embodiments, the substrate comprises a substrate material that may show poor adhesion to cobalt. Non-limiting examples of substrates with poor adhesion to cobalt include titanium nitride (TiN), tantalum nitride (TaN), titanium silicon nitride (TiSiN), aluminum-doped titanium carbide (TiAlC), or combinations thereof.

The substrate 200 is not limited to any particular size or shape. The substrate can be a round wafer having a 200 mm diameter, a 300 mm diameter or other diameters, such as 450 mm, among others. The substrate can also be any polygonal, square, rectangular, curved or otherwise non-circular workpiece, such as a polygonal glass substrate used in the fabrication of flat panel displays.

The trench 202 may be formed by etching the substrate 200 using any suitable etch process. In some embodiments, the trench 202 is defined by one or more sidewalls 214, a bottom surface 206 and upper corners 221. In some embodiments, the trench 202 may have a high aspect ratio, e.g., an aspect ratio between about of about 5:1 and about 20:1. As used herein, the aspect ratio is the ratio of a depth 207 of the feature to a width 209 of the feature. In embodiments, the trench 202 has a width 209 less than or equal to 20 nanometers, less than or equal to 10 nanometers, or a width 209 between 5 to 10 nanometers.

Referring to FIG. 2A-C, substrate 200 may comprise or consist of a material that does not typically show good adhesion, or bonding with a thin cobalt layer 230 such as a film having a thickness less than 1 micrometer or less than 50 nanometers. Non-limiting materials that may not show good adhesion, or bonding to cobalt thin films include a layer of titanium nitride (TiN), tantalum nitride (TaN), titanium silicon nitride (TiSiN), aluminum-doped titanium carbide (TiAlC), or combinations thereof. In some embodiments, substrate 200 comprises a layer of such material provided as an underlayer 208 optionally deposited on substrate 200 and within trench 202 in a process chamber configured to deposit a layer. Although the following description is made with respect to underlayer 208 appearing as a separate layer from substrate 200, the substrate 200 may be comprised of or consist of underlayer 208 as described below. The underlayer 208 can be a layer conformably formed along at least a portion of the sidewalls 214 and/or bottom surface 206 of a feature such as trench 202 such that a substantial portion of the feature prior to the deposition of the layer remains unfilled after deposition of the layer. In some embodiments, the underlayer may be formed along the entirety of the sidewalls 214 and bottom surface 206 of the trench 202.

Referring to FIG. 2B, substrate 200 includes underlayer 208 deposited atop the substrate 200 and within the trench 202. In embodiments, underlayer 208 comprises at least one of titanium nitride (TiN), or tantalum nitride (TaN), which do not bond or adhere well to cobalt. In embodiments, the underlayer 208 is a titanium nitride (TiN), or tantalum nitride (TaN) film or titanium nitride (TiN), or tantalum nitride (TaN)-containing film resulting from the CVD and ALD processing. In some embodiments, as shown in FIG. 2B, the underlayer 208 is deposited atop a surface 222 of the substrate 200 and within the trench 202 formed in the surface 222. The underlayer 208 may be deposited using any suitable CVD deposition process(es). In some embodiments, the underlayer 208 is deposited via a CVD process using suitable titanium or tantalum precursors. Suitable process conditions for depositing underlayer 208 include process conditions, such as temperature suitable to heat the substrate at a temperature in the range from about 100° C. to about 600° C., or in the range from about 200° C. to about 500° C., or in the range from about 300° C. to about 450° C. In embodiments, the process chamber is maintained at a pressure in the range from about 1 Torr to about 150 Torr, or in the range from about 5 Torr to about 90 Torr. In some embodiments, the thickness of the underlayer 208 is predetermined such as about 5 angstroms to about 150 angstroms, or about 5 angstroms to about 15 angstroms, or about 10 angstroms. In embodiments, the shape of the underlayer 208 is substantially uniform and conformal as generally shown in FIGS. 2B, however variation may occur.

Referring to FIG. 1, FIGS. 2A-C, embodiments of the present disclosure include a method 100 of forming a cobalt layer 230 on a substrate 200 such as a substrate including underlayer 208 disposed in a process chamber, including at 102: (a) exposing the substrate 200 to a first process gas including a bonding agent in an amount sufficient to facilitate bonding or adhesion of cobalt to a first surface 215 of the substrate 200; and at 104 depositing cobalt layer 230 upon the first surface 215 of the substrate 200 to form a cobalt layer 230.

In embodiments, at 102, the first surface 215 is exposed to a first process gas comprising a bonding agent. In embodiments, exposure of the first surface 215 is a soak process lasting in a range from about 1 second to about 90 seconds, such as 30 to 60 seconds, or around 60 seconds. In embodiments, exposure of the first surface 215 is a soak process at a temperature of from about 150 degrees Celsius to about 350 degrees Celsius. In embodiments, the soak process occurs under the same or substantially similar process condition, such as temperature and pressure of the CVD or ALD process that deposited the underlayer 208 of substrate 200. In embodiments, a pulse of a bonding agent accompanied with a suitable carrier gas is introduced into the process chamber. The bonding agent may be the same compound as the gas used for the soak process or alternatively, the bonding agent may be a different compound, depending on the product throughput requirements and the device applications. For example, in embodiments, where the first surface 215 is titanium nitride or tantalum nitride film, suitable bonding agent may be may include a silane precursor, such as SiH₄. In embodiments, a silane precursor or other silicon containing material may be suitable wherein the substrate or underlayer thereof comprises titanium nitride (TiN), tantalum nitride (TaN), titanium silicon nitride (TiSiN), aluminum-doped titanium carbide (TiAlC), or combinations thereof. In embodiments, the bonding agent such as silane or other silicon containing material is suitable for forming a chemical bond between the cobalt and the substrate. For example, bonding agent suitable for forming a chemical bond between the cobalt, such as cobalt subsequently deposited by chemical vapor deposition, and the substrate includes one or more silanes. In embodiments the bonding agent forms a layer such as a CoSix (wherein x is an integer such as 1, 2 or more) layer provided to bond a metal layer disposed upon the underlayer 208. In embodiments, SiH₄ forms a bonded layer of CoSix (wherein x is an integer such as 1 or 2) atop a layer of TiN by absorption/thermal decomposition. In some embodiments, cobalt bonds with silicon to form CoSix to form improved, stable layers thereon. In embodiments, the cobalt subsequently deposited atop a bonded cobalt layer is cobalt having a purity of 80%, 90%, 95%, 99%, 99.999% or more.

In embodiments, the underlayer 208 may be formed with multiple silane or silicon containing material soaks. For example, depending upon the thickness of the underlayer 208, intermittent soaking may occur in intervals such as after the deposition of ten angstroms of underlayer material. For example, in forming a thirty angstrom underlayer, the underlayer formation may stop after ten angstroms is deposited and then restarted after a silane soak. The silane or silicon containing material soak process may be repeated after deposition of another ten angstroms of underlayer material. In embodiments including intermittent soaking of silane on the underlayer, such as TiN, a silane soak may occur for about 1 minute at a temperature in the amount of 325 degrees Celsius to 350 degrees Celsius, or about 340 degrees Celsius.

In other embodiments, only the first surface 215 of the underlayer 208 is soaked, where the first surface 215 is the outer most layer of the underlayer 208. In embodiments, a silane or silicon containing material soak upon the first surface 215 may occur for about 1 minute at about 175 degrees Celsius. In some embodiments, the silane or silicon containing material soak leads to CO—Si bond formation, without impact on the underlayer 208 or first surface 215 thereof. In some embodiments, a layer 225 (shown in phantom in FIG. 2B) is formed upon the first surface 215 which is a layer of CO—Si bonded material. In embodiments, layer 225 is a monolayer. In embodiments, layer 225 has a thickness of 0.5 to 10 angstroms. In some embodiments, the silane soak or silicon containing material soak leads to a covalent bond formed between CO and Si such as CO—Si. In embodiments, the bond formation increases the quality of the cobalt formed upon a substrate such as layer 230 in FIG. 2C that may typically show poor adhesion to cobalt such as TiN, TaN, and the like. In embodiments, the cobalt layer such as layer 230 subsequently deposited thereon is a high purity, low resistivity cobalt layer. In embodiments, the cobalt subsequently deposited atop a bonded cobalt layer is cobalt having a purity of 80%, 90%, 95%, 99%, 99.999% or more.

In embodiments, silanes may include saturated chemical compounds including one or multiple silicon atoms linked to each other or one or multiple atoms of other chemical elements as the tetrahedral centers of multiple single bonds. In embodiments, silanes suitable for use in accordance with the present disclosure include trichlorosilane, tetramethylsilane, tetraethoxysilane, or an inorganic compound with chemical formula SiH₄. In embodiments, a silane is characterized as a group 14 hyrdride. Other suitable silanes for use herein may include other silicon containing materials such as disilane, trisilane, tetrasilane, pentasilane and combinations thereof.

In some embodiments, the bonding agent is suitable for promoting adhesion between the cobalt and the first surface of the substrate. A non-limiting example of a bonding agent suitable for promoting adhesion between the cobalt and the first surface of the substrate is one or more carbonyl compounds. Non-limiting examples of suitable one or more carbonyl compounds include molybdenum compounds for use in promoting adhesion between the cobalt and the first surface of the substrate. Non-limiting suitable molybdenum compounds include one or more of molybdenum carbonyl complexes, molybdenum carbonyls such as molybdenum hexacarbonyl, bis(ethylbenzene)molybdenum, cycloheptatriene molybdenum tricarbonyl, bis(t-butylimido)bis(dimethylamino)molybdenum (VI), molybdenum(VI) fluoride, (methyphosphonous chloride)pentacarbonyl molybdenum, dimethylphosphonous dichloride)pentacarbonyl molybdenum, and combinations thereof. Suitable molybdenum compounds may be provided to process chamber 16 in a gaseous form, formed from liquid or solid precursor material. Other bonding agents suitable for promoting adhesion, or adhesion promoters may include one or more metals suitable for forming an alloy with cobalt, such as ruthenium and iridium. The addition of an adhesion promoter improves the adhesion between the cobalt layer and the substrate, such as substrates that do not adhere well to cobalt. In some embodiments, the addition of an adhesion promoter promotes the formation of a cobalt alloy (shown in this embodiment as layer 225 in phantom in FIG. 2B) such as the combination of the adhesion promoter with cobalt to increase the adhesion of the cobalt layer to the substrate, such as TiN and TaN. In embodiments, adhesion promoting compositions including metal species such as molybdenum, ruthenium and iridium can be contacted with the first surface of the substrate in an amount effective to yield improved adhesion between the substrate and cobalt layer(s) applied. Improved adhesion may be qualitatively observed or checked using known methods in the art such as a four point bending test or tape test performed at room temperature applying tape such as 3M brand tape to the cobalt layer and pulling the tape. In embodiments, adhesion promoting compositions including metal species that can form an alloy structure with cobalt, and form a monolayer of alloy (shown in this embodiment as layer 225 in phantom in FIG. 2B) atop the first surface of the substrate.

Following application of the adhesion promoting composition to a substrate, time may pass prior to applying the cobalt layer by a chemical vapor deposition to the substrate including the adhesion promoter. The amount of time may vary depending on the adhesion promoter selected. Further, the temperature during the time between application of the adhesion promoting composition and application of the cobalt layer may also vary. In a non-limiting embodiment, the time may be 10 seconds to 1 minute and the temperature may be ambient temperature. In a further non-limiting embodiment, the time is thirty (30) minutes.

In embodiments, depending upon the thickness of the cobalt layer 230, intermittent soaking with one or more carbonyl compounds such as molybdenum carbonyl compounds or adhesion promoters may occur in intervals such as after the deposition of ten angstroms of cobalt layer 230 material. For example, in forming a thirty angstrom cobalt layer, the cobalt layer 230 formation may stop after ten angstroms is deposited and then restarted after one or more carbonyl compounds contacts the cobalt layer 230 material under conditions suitable for forming a carbonyl layer on the cobalt layer 230 material, the carbonyl layer having a thickness of 1 to 100 angstroms atop a first cobalt layer. The process may be repeated after deposition of another ten angstroms of cobalt material. In embodiments including intermittent soaking of carbonyl on or within the cobalt layer, may occur for about 5 seconds to 1 minute at a temperature in the amount of 150 degrees Celsius to 200 degrees Celsius, or about 175 degrees Celsius.

Referring to FIG. 2C, and FIG. 1 at 104 method of the present disclosure include depositing cobalt layer 230 upon the first surface 215 of the substrate 200 to form a cobalt layer 230. Although not shown in FIG. 2C, method of the present disclosure include depositing cobalt layer 230 upon layer 225 of FIG. 2B as described above, which may comprise a cobalt alloy or in embodiments a layer of bonded Co—Si as described above. For example, although not shown in FIG. 2C, layer 225 may be between cobalt layer 230 and first surface 215. In embodiments, layer 225 may be a cobalt alloy as described above. In embodiments, layer 225 may be a layer of bonded Co—Si. In embodiments, a cobalt layer 230 may be formed by process techniques such as chemical vapor deposition (CVD), atomic layer deposition (ALD), physical vapor deposition (PVD), derivatives thereof and combinations thereof. The cobalt layer 230 may be deposited to a thickness of at least about 30 angstroms, such as in a range from about 30 angstroms to about 200 angstroms. In one example, a cobalt layer 230 is deposited on the first surface 215 or layer 225 by an ALD process by using a TiN underlayer as part of substrate 200. In another example, a cobalt layer 230 is deposited on the first surface 215 or in embodiments layer 225 by an ALD process by using a TaN underlayer as part of substrate 200.

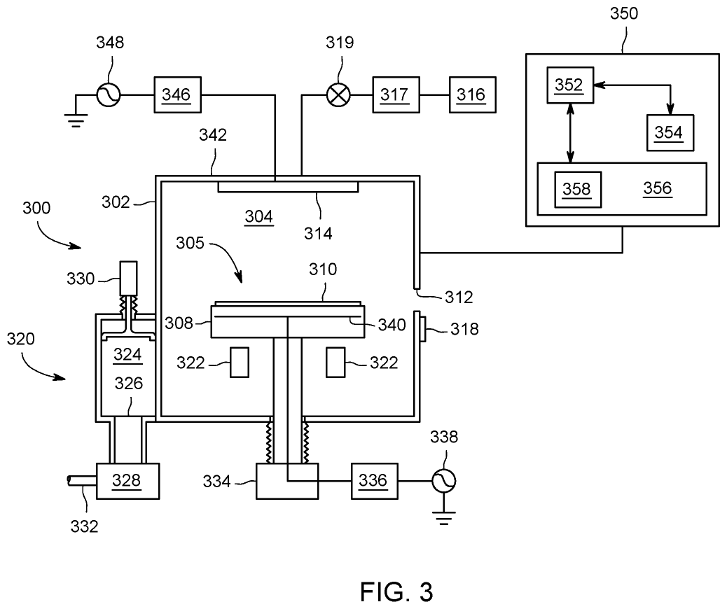

FIG. 3 described below depicts an apparatus 300 suitable for processing a substrate in accordance with some embodiments of the present disclosure. The apparatus 300 may comprise a controller 350 and a process chamber 302 having an exhaust system 320 for removing excess process gases, processing by-products, or the like, from the interior of the process chamber 302. Exemplary process chambers may include the DPS®, ENABLER®, ADVANTEDGE™, AVATAR™, or other process chambers, available from Applied Materials, Inc. of Santa Clara, Calif. Other suitable process chambers may similarly be used.

The process chamber 302 has an inner volume 305 that may include a processing volume 304. The processing volume 304 may be defined, for example, between a substrate support pedestal 308 disposed within the process chamber 302 for supporting a substrate 310 during processing and one or more gas inlets, such as a showerhead 314 and/or nozzles provided at predetermined locations. In some embodiments, the substrate support pedestal 308 may include a mechanism that retains or supports the substrate 310 on the surface of the substrate support pedestal 308, such as an electrostatic chuck, a vacuum chuck, a substrate retaining clamp, or the like (not shown). In some embodiments, the substrate support pedestal 308 may include mechanisms for controlling the substrate temperature (such as heating and/or cooling devices, not shown) and/or for controlling the species flux and/or ion energy proximate the substrate surface. In embodiments, the substrate temperature may be maintained at a temperature between about 30 to 400 degrees Celsius. In embodiments, process chamber conditions described herein are suitable for reacting a process gas comprising a bonding agent in an amount sufficient to facilitate bonding or adhesion of cobalt to a first surface of the substrate as described herein.

In some embodiments, the substrate support pedestal 308 may include an RF bias electrode 340. In embodiments, the RF bias electrode 340 may be coupled to one or more RF bias power sources (RF power source 338 shown in FIG. 3) through one or more respective waveform adjusters (a first bias waveform adjuster 336 shown) capable of adjusting various voltage waveforms supplied to an electric apparatus.

In some embodiments, the apparatus 300 may utilize capacitively coupled RF power for plasma processing, although the apparatus may also or alternatively use inductive coupling of RF power for plasma processing. For example, the process chamber 302 may have a ceiling 342 made from dielectric materials and a showerhead 314 that is at least partially conductive to provide an RF electrode or a separate RF electrode may be provided. The showerhead 314 (or other RF electrode) may be coupled to one or more RF power sources (RF power source 348 shown) through one or more respective waveform adjusters (a first source waveform adjuster 346 shown).

In embodiments, the substrate 310 (in FIG. 3) may enter the process chamber 302 via an opening 312 in a wall of the process chamber 302. The opening 312 may be selectively sealed via a slit valve 318, or other mechanism for selectively providing access to the interior of the chamber through the opening 312. The substrate support pedestal 308 may be coupled to a lift mechanism 334 that may control the position of the substrate support pedestal 308 between a lower position (as shown) suitable for transferring substrates into and out of the chamber via the opening 312 and a selectable upper position suitable for processing. The process position may be selected to maximize process uniformity for a particular process. When in at least one of the elevated processing positions, the substrate support pedestal 308 may be disposed above the opening 312 to provide a symmetrical processing region.

The one or more gas inlets (e.g., the showerhead 314) may be coupled to a gas supply 316 for providing one or more process gases through a mass flow controller 317 into the processing volume 304 of the process chamber 302. In addition, one or more valves 319 may be provided to control the flow of the one or more process gases. The mass flow controller 317 and one or more valves 319 may be used individually, or in conjunction to provide the process gases at predetermined flow rates at a constant flow rate, or pulsed (as described above).

Although a showerhead 314 is shown in FIG. 3, additional or alternative gas inlets may be provided such as nozzles or inlets disposed in the ceiling or on the sidewalls of the process chamber 302 or at other locations suitable for providing gases to the process chamber 302, such as the base of the process chamber, the periphery of the substrate support pedestal, or the like.

The exhaust system 320 generally includes a pumping plenum 324 and one or more conduits that couple the pumping plenum 324 to the inner volume 305 (and generally, the processing volume 304) of the process chamber 302.

A vacuum pump 328 may be coupled to the pumping plenum 324 via a pumping port 326 for pumping out the exhaust gases from the process chamber via one or more exhaust ports (two exhaust ports 322 shown). 302. The vacuum pump 328 may be fluidly coupled to an exhaust outlet 332 for routing the exhaust to appropriate exhaust handling equipment. A valve 330 (such as a gate valve, or the like) may be disposed in the pumping plenum 324 to facilitate control of the flow rate of the exhaust gases in combination with the operation of the vacuum pump 328. Although a z-motion gate valve is shown, any suitable, process compatible valve for controlling the flow of the exhaust may be utilized.

To facilitate control of the process chamber 302 as described above, the controller 350 may be any form of general-purpose computer processor that can be used in an industrial setting for controlling various chambers and sub-processors. The memory, or computer-readable medium, 356 of the CPU 352 may be one or more of readily available memory such as random access memory (RAM), read only memory (ROM), floppy disk, hard disk, or any other form of digital storage, local or remote. The support circuits 354 are coupled to the CPU 352 for supporting the processor in a conventional manner. These circuits include cache, power supplies, clock circuits, input/output circuitry and subsystems, and the like.

The inventive methods disclosed herein may generally be stored in the memory 356 as a software routine 358 that, when executed by the CPU 352, causes the process chamber 302 to perform processes of the present disclosure. The software routine 358 may also be stored and/or executed by a second CPU (not shown) that is remotely located from the hardware being controlled by the CPU 352. Some or all of the method of the present disclosure may also be performed in hardware. As such, the disclosure may be implemented in software and executed using a computer system, in hardware as, e.g., an application specific integrated circuit or other type of hardware implementation, or as a combination of software and hardware. The software routine 358 may be executed after the substrate 310 is positioned on the substrate support pedestal 308. The software routine 358, when executed by the CPU 352, transforms the general purpose computer into a specific purpose computer (controller) 350 that controls the chamber operation such that the methods disclosed herein are performed.

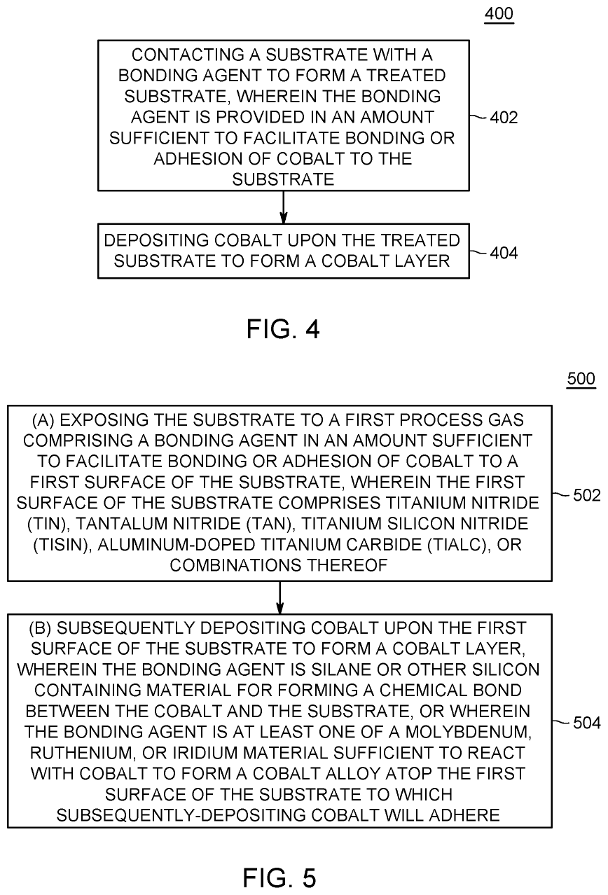

Referring now to FIG. 4, a method of depositing a cobalt film is described. Initially, at 402, the method 400 includes contacting a substrate 200 with a bonding agent to form a treated substrate, wherein the bonding agent is provided in an amount sufficient to facilitate bonding of cobalt to the substrate; and at 404 depositing cobalt upon the treated substrate to form a cobalt layer. In embodiments, method 400 includes bonding agent suitable for forming a chemical bond between the cobalt and the substrate. In embodiments, the bonding agent is one or more silanes or silicon containing materials as described above. In some embodiments, the bonding agent is suitable for promoting adhesion between the cobalt and the treated substrate, for example, the bonding agent may be one or more carbonyl compounds. In embodiments, the substrate comprises or consists of a layer of titanium nitride (TiN), tantalum nitride (TaN), titanium silicon nitride (TiSiN), aluminum-doped titanium carbide (TiAlC), or combinations thereof. In some embodiments, the bonding agent is provided in an amount sufficient to form a layer of COSix directly upon a first surface of the substrate, wherein x is an integer. In one embodiment, the bonding agent comprises one or more silanes, and wherein the silane contacts a first surface of the substrate for 40 to 100 seconds at a temperature of about 150 to 200 degrees Celsius. In one embodiment, the bonding agent comprises one or more molybdenium carbonyl compounds contacted with a substrate in need thereof for 3 to 10 seconds at a temperature of about 150 to 225 degrees Celsius. In embodiments, the bonding agent comprises one or more molybdenum carbonyl compounds, wherein the one or more molybdenum carbonyl compounds contacts a first surface of the substrate for 3 to 10 seconds at a temperature of about 150 to 225 degrees Celsius. In embodiments, the cobalt layer formed by processes of the present disclosure is characterized as a void-free cobalt layer.

Referring now to FIG. 5, a method 500 of bonding or adhering a cobalt layer to a substrate 200 disposed in a process chamber is shown. The method 500 may be performed, for example, in a suitable cluster tool and process chambers. Exemplary processing systems that may be used to perform the methods disclosed herein may include, but are not limited to, any of the ENDURA®, CENTURA®, or PRODUCER® brand processing systems, commercially available from Applied Materials, Inc., of Santa Clara, Calif. Other process chambers, including ones available from other manufacturers, may also be suitably used in connection with the teachings provided herein. The method 500 is typically performed on a substrate 200 as described above, under conditions described above. In embodiments, the process sequence includes at 502 exposing the substrate to a first process gas including a bonding agent in an amount sufficient to facilitate bonding or adhesion of cobalt to a first surface of the substrate, wherein the first surface of the substrate comprises titanium nitride (TiN), tantalum nitride (TaN), titanium silicon nitride (TiSiN), aluminum-doped titanium carbide (TiAlC), or combinations thereof. In embodiments, the bonding agent is one or more silanes or silicon containing materials as described above for forming a chemical bond between the cobalt and the substrate, and wherein the substrate includes a layer of titanium nitride (TiN), tantalum nitride (TaN), titanium silicon nitride (TiSiN), aluminum-doped titanium carbide (TiAlC), or combinations thereof. In embodiments, the one or more silanes comprises or consists of SiH₄. In embodiments, the bonding agent is suitable for promoting adhesion between the cobalt and the first surface of the substrate by forming a cobalt alloy mono-layer atop the substrate or first surface thereof, wherein the substrate comprises a layer of titanium nitride (TiN), tantalum nitride (TaN), titanium silicon nitride (TiSiN), aluminum-doped titanium carbide (TiAlC), or combinations thereof. In embodiments the bonding agent includes a metal species suitable for forming an alloy with cobalt, wherein the metal species is one or more molybdenum carbonyl compounds, ruthenium compounds, or iridium compounds. In embodiments, the bonding agent improves adhesion between the first surface of the substrate and the cobalt layer to provide a high purity, low resistivity cobalt layer.

Referring now to FIG. 5 at 504, the method may include (b) subsequently depositing cobalt upon the first surface of the substrate to form a cobalt layer, wherein the bonding agent is silane or other silicon containing material for forming a chemical bond between the cobalt and the substrate, or wherein the bonding agent is at least one of a molybdenum, ruthenium, or iridium material sufficient to react with cobalt to form a cobalt alloy atop the first surface of the substrate to which subsequently-depositing cobalt will adhere. In embodiments, suitable alloys of cobalt formed for example, as layer 225 shown in FIG. 2B, may include molybdenum cobalt alloy which may be substantially pure such that it does not contain significant amounts of additional metals or materials. Non-limiting examples of molybdenum cobalt alloys include alloys comprising between about 60 to 80 weight percent cobalt and 20 to 40 weight percent molybdenum, wherein weight percent is based on the total weight of the alloy composition. In embodiments molybdenum cobalt alloys include cobalt at approximately 75 weight percent and molybdenum at approximately 25 weight percent. In embodiments the cobalt alloy includes a cobalt-iridium alloy (Co—Ir) or a cobalt-ruthenium alloy (Co—Ru). In embodiments, Co—Ru, Co—Ir, and Co—Mo alloys are provided in a predetermined thickness such as a monolayer atop the first surface of the substrate. In embodiments, Co—Ru, Co—Ir, and Co—Mo alloys are provided in a predetermined thickness such 0.5 to 1 angstrom atop the first surface of the substrate.

In embodiments, molybdenum, ruthenium, or iridium material such as a monolayer of alloy thereof improves adhesion between the first surface of the substrate and the cobalt layer to provide a high purity, low resistivity cobalt layer. In embodiments the cobalt layer is characterized as a void-free cobalt layer with reduced delamination or cracking between the cobalt layer and the substrate. In embodiments, the method comprises purging the bonding agent from the process chamber prior to depositing cobalt upon the first surface.

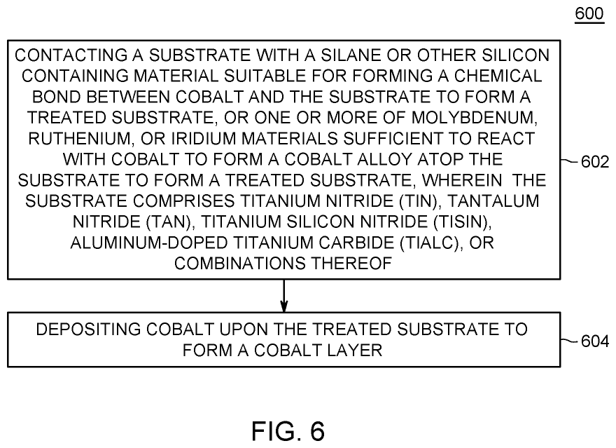

Referring now to FIG. 6, a method 600 depositing a cobalt film, such as on a substrate 200 disposed in a process chamber is shown. The method 600 may be performed, for example, in a suitable cluster tool and process chambers. Exemplary processing systems that may be used to perform the methods disclosed herein may include, but are not limited to, any of the ENDURA®, CENTURA®, or PRODUCER® brand processing systems, commercially available from Applied Materials, Inc., of Santa Clara, Calif. Other process chambers, including ones available from other manufacturers, may also be suitably used in connection with the teachings provided herein. The method 600 is typically performed on a substrate 200 as described above, under conditions described above. In embodiments, the process sequence includes at 602 contacting a substrate with a silane or other silicon containing material suitable for forming a chemical bond between cobalt and the substrate to form a treated substrate, or one or more of molybdenum, ruthenium, or iridium materials sufficient to react with cobalt to form a cobalt alloy atop the substrate to form a treated substrate, wherein the substrate comprises titanium nitride (TiN), tantalum nitride (TaN), titanium silicon nitride (TiSiN), aluminum-doped titanium carbide (TiAlC), or combinations thereof. In embodiments, the silane or other silicon containing material is provided in an amount sufficient to form a chemical bond between the cobalt and the substrate. In embodiments, the silane comprises or consists of SiH₄. In embodiments, one or more of molybdenum, ruthenium, or iridium materials are provided in an amount sufficient for promoting adhesion between the cobalt and the treated substrate. In some embodiments, the one or more of molybdenum, ruthenium, or iridium materials comprises one or more carbonyl compounds. In embodiments, the substrate comprises a layer of titanium nitride (TiN), tantalum nitride (TaN), titanium silicon nitride (TiSiN), aluminum-doped titanium carbide (TiAlC), or combinations thereof. In embodiments, the silane or other silicon containing material is provided in an amount sufficient to form a layer of COSix directly upon a first surface of the substrate, wherein x is an integer. In embodiments, the silane contacts a first surface of the substrate for 40 to 100 seconds at a temperature of about 150 to 200 degrees Celsius. In some embodiments, the one or more of molybdenum, ruthenium, or iridium materials comprises one or more molybdenum carbonyl compounds, and wherein the one or more molybdenum carbonyl compounds contacts a first surface of the substrate for 3 to 10 seconds at a temperature of about 150 to 225 degrees Celsius. In some embodiments, the bonding agent is applied in an amount sufficient to form an atomic layer of bonding agent upon the first surface of the substrate. In embodiments, alloy is formed at an interface between the top surface of the substrate and a subsequently formed substantially pure cobalt layer.

In embodiments, the process sequence includes at 604 depositing cobalt upon the treated substrate to form a cobalt layer. In embodiments, cobalt is deposited with high purity. In embodiments, cobalt is deposited in an amount sufficient to form a layer as described above, or in an amount to fill or overfill a feature.

While the foregoing is directed to embodiments of the present disclosure, other and further embodiments of the disclosure may be devised without departing from the basic scope thereof.

1. A method of bonding or adhering a cobalt layer to a substrate disposed in a process chamber, comprising:
(a) exposing the substrate to a first process gas comprising a bonding agent in an amount sufficient to facilitate bonding or adhesion of cobalt to a first surface of the substrate, wherein the first surface of the substrate comprises titanium nitride (TiN), tantalum nitride (TaN), titanium silicon nitride (TiSiN), aluminum-doped titanium carbide (TiAlC), or combinations thereof; and
(b) subsequently depositing cobalt upon the first surface of the substrate to form a cobalt layer, wherein the bonding agent is silane or other silicon containing material for forming a chemical bond between the cobalt and the substrate, or wherein the bonding agent is at least one of a molybdenum, ruthenium, or iridium material sufficient to react with cobalt to form a cobalt alloy atop the first surface of the substrate to which subsequently-depositing cobalt will adhere.

2. The method of claim 1, wherein the bonding agent is one or more silanes for forming a chemical bond between the cobalt and the substrate, and wherein the substrate comprises a layer of titanium nitride (TiN), tantalum nitride (TaN), titanium silicon nitride (TiSiN), aluminum-doped titanium carbide (TiAlC), or combinations thereof.

3. The method of claim 2, wherein the one or more silanes comprises or consists of SiH₄.

4. The method of claim 1, wherein the bonding agent is suitable for promoting adhesion between the cobalt and the first surface of the substrate by forming a cobalt alloy mono-layer atop the substrate, and wherein the substrate comprises a layer of titanium nitride (TiN), tantalum nitride (TaN), titanium silicon nitride (TiSiN), aluminum-doped titanium carbide (TiAlC), or combinations thereof.

5. The method of claim 4, wherein the bonding agent comprises a metal species suitable for forming an alloy with cobalt, wherein the metal species is one or more molybdenum carbonyl compounds, ruthenium compounds, or iridium compounds.

6. The method of claim 1, wherein the bonding agent improves adhesion between the first surface of the substrate and the cobalt layer to provide a high purity, low resistivity cobalt layer.

7. The method of claim 1, wherein the cobalt layer is characterized as a void-free cobalt layer with reduced delamination or cracking between the cobalt layer and the substrate.

8. The method of claim 1, wherein the substrate comprises a feature formed in the first surface of the substrate, wherein the feature comprises sidewalls and a bottom surface.

9. The method of claim 1, wherein the substrate comprises a layer of titanium nitride (TiN), tantalum nitride (TaN), titanium silicon nitride (TiSiN), aluminum-doped titanium carbide (TiAlC), or combinations thereof.

10. The method of claim 1, further comprising purging the bonding agent from the process chamber prior to depositing cobalt upon the first surface.

11. A method of depositing a cobalt film, comprising:
contacting a substrate with a silane or other silicon containing material suitable for forming a chemical bond between cobalt and the substrate to form a treated substrate, or one or more of molybdenum, ruthenium, or iridium materials sufficient to react with cobalt to form a cobalt alloy atop the substrate to form a treated substrate, wherein the substrate comprises titanium nitride (TiN), tantalum nitride (TaN), titanium silicon nitride (TiSiN), aluminum-doped titanium carbide (TiAlC), or combinations thereof; and
depositing cobalt upon the treated substrate to form a cobalt layer.

12. The method of claim 11, wherein the silane or other silicon containing material is provided in an amount sufficient to form a chemical bond between the cobalt and the substrate.

13. The method of claim 11, wherein the silane comprises or consists of SiH₄.

14. The method of claim 11, wherein one or more of molybdenum, ruthenium, or iridium materials are provided in an amount sufficient for promoting adhesion between the cobalt and the treated substrate.

15. The method of claim 14, wherein the one or more of molybdenum, ruthenium, or iridium materials comprises one or more carbonyl compounds.

16. The method of claim 11, wherein the substrate comprises a layer of titanium nitride (TiN), tantalum nitride (TaN), titanium silicon nitride (TiSiN), aluminum-doped titanium carbide (TiAlC), or combinations thereof.

17. The method of claim 11, wherein the silane or other silicon containing material is provided in an amount sufficient to form a layer of COSix directly upon a first surface of the substrate, wherein x is an integer.

18. The method of claim 11, wherein the silane contacts a first surface of the substrate for 40 to 100 seconds at a temperature of about 150 to 200 degrees Celsius.

19. The method of claim 11, wherein the one or more of molybdenum, ruthenium, or iridium materials comprises one or more molybdenum carbonyl compounds, and wherein the one or more molybdenum carbonyl compounds contacts a first surface of the substrate for 3 to 10 seconds at a temperature of about 150 to 225 degrees Celsius.

20. A computer readable medium, having instructions stored thereon which, when executed, cause a process chamber to perform a method of bonding or adhering a cobalt layer to a substrate disposed in a process chamber, the method comprising:
(a) exposing the substrate to a first process gas comprising a bonding agent in an amount sufficient to facilitate bonding or adhesion of cobalt to a first surface of the substrate, wherein the first surface of the substrate comprises titanium nitride (TiN), tantalum nitride (TaN), titanium silicon nitride (TiSiN), aluminum-doped titanium carbide (TiAlC), or combinations thereof; and
(b) subsequently depositing cobalt upon the first surface of the substrate to form a cobalt layer, wherein the bonding agent is silane or other silicon containing material for forming a chemical bond between the cobalt and the substrate, or wherein the bonding agent is at least one of a molybdenum, ruthenium, or iridium material sufficient to react with cobalt to form a cobalt alloy atop the first surface of the substrate to which subsequently-depositing cobalt will adhere.
